(19) United States
(12) Patent Application Publication
(10) Pub. No.: US 2007/0066095 A1
(43) Pub. Date: Mar. 22, 2007

(54) Switch device

(75) Inventors: Wei-Chen Huang, Taipei (TW); Cheng-Lung Hung, Taipei (TW)

Correspondence Address: BIRCH STEWART KOLASCH & BIRCH, PO BOX 747, FALLS CHURCH, VA, 22040-0747, US

(73) Assignee: EMINE TECHNOLOGY COMPANY, LTD.

(21) Appl. No.: 11/341,494

(22) Filed: Jan. 30, 2006

(30) Foreign Application Priority Data
Sep. 16, 2005 (TW) 094216008

(51) Int. Cl. H05K 1/00

(52) U.S. Cl. 439/76.1

(57) ABSTRACT

A switch device makes at least a controlled device controllable by a control element. The control element is connected to signal ports mounted on a circuit board of the switch device. There are signal lines connected between the circuit board and the controlled devices. Besides, the signal lines and the circuit board are connected via a removable plug and socket combination.

### CROSS-REFERENCE TO RELATED APPLICATIONS

This non-provisional application claims priority under 35 U.S.C. § 119(a) on Patent Application No(s). 094216008 filed in Taiwan, R.O.C. on Sep. 16, 2005, the entire contents of which are hereby incorporated by reference.

### BACKGROUND OF THE INVENTION

1. Field of Invention

The invention generally relates to a switch device, and in particular relates to a switch device for connecting signal lines to a circuit board through a plug and socket combination.

2. Related Art

For industry computers or server computers, there are possibly many main boards and central processors in the same cabinet. Each group of main board and central processor forms a computer unit. Therefore, in a cabinet there are many computer units. To control the computer units, user has to operate through input/output elements, such as keyboard, mouse and monitor. However, it is impractical to setup each computer unit a separated keyboard, mouse and monitor. Therefore, an automatic switch can be applied to share a group of keyboard, mouse, and monitor with each computer unit. Moreover, as the price of home-use computers being reducing, it is common that one owns at least one computer. For those people having busy affairs, using two or more computers are also usual. Therefore, the automatic switch for server is gradually expanded to general home use. The most common application is a one-for-two automatic switch that shares a set of keyboard, mouse, and monitor to respectively control two computers. A relative prior art is disclosed in Taiwan Laid-open Patent No. 584276. It is an automatic switch having a main plug body and at least two signal sockets. The main plug body encloses a circuit board for switching circuits and wires connecting to the signal sockets for signal transmission. The signal sockets include sockets for connecting to signals of monitor, keyboard, and mouse. The main plug body is formed by multiple injections. It contains an inner protection layer to cover the circuit board; an outer shell to cover the protection layer; and an anti-slide surface to cover a part of the outer shell. The protection layer, outer shell, and anti-slide surface are formed as a unit. The signal wires are directly soldered to the circuit board inside the unit.

Further referring to FIG. 1, a descriptive view of signal wire and circuit board connection in a conventional automatic switch, the signal lines 110 are connected to two computers (not shown in the drawing). The other side of the automatic switch is equipped with three connection ports 100 for respective connections with a keyboard, a mouse, and a monitor (not shown). The signal lines 110 are directly soldered to the circuit board 130. However, since each signal line 110 include many signal wires, the wires in FIG. 1 and aforesaid Taiwan Patent 584276 directly soldered to the circuit boards are easily misallocated, insufficient soldered and caused disconnection and low yield rate. Moreover, when one repairing a damaged signal line, each wire has to be removed from the circuit board. Then, each wire of the new line has to be soldered one by one to the circuit board again. The process should be very carefully done. Otherwise, wire misallocation will cause futile and repeated efforts.

### SUMMARY OF THE INVENTION

In view of the above-problem, the object of the invention is to provide a switch device for connecting signal lines to a circuit board through a plug and socket combination so as to improve yield rate and simplify line replacement.

To achieve the aforesaid object, a switch device of the invention makes at least a controlled device controllable by a control element. The switch device has a shell for mounting therein a circuit board that switches signals to different controlled devices. The circuit board is electrically connected to signal lines through sockets thereon. The signal lines are connected to at least a controlled device. In addition, the signal ports are used to connect the control element so that the control element can switch and connect to the different controlled devices via the circuit board of the switch device.

The electric connections between the signal lines and the circuit board are achieved by way of plug and socket combination. That is, the signal lines are formed with a plug to be connected to a socket mounted on the circuit board. The plug connected to the socket achieves signal connection.

Therefore, by way of the invention, the connections between signal lines and the circuit board of a switch device are achieved by a plug and socket combination. It makes the connection of signal lines and a circuit board easy and accurate. It reduces the mistakes in manufacturing process and improves the yield rate of production.

Moreover, because the signal lines are easy to be damaged as being exposed to the environment, thus a damaged line can be easily removed from the circuit board by being unplugged from the socket. Further, a replacement signal line can be easily connected to the circuit board by being plugged to the socket. The plug and socket makes the replacement of signal line easy and accurate.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The invention will become more fully understood from the detailed description given hereinbelow. However, this description is for purposes of illustration only, and thus is not limitative of the invention, wherein:

FIG. 1 is a descriptive view of a conventional switch device showing a connection of signal lines and a circuit board;

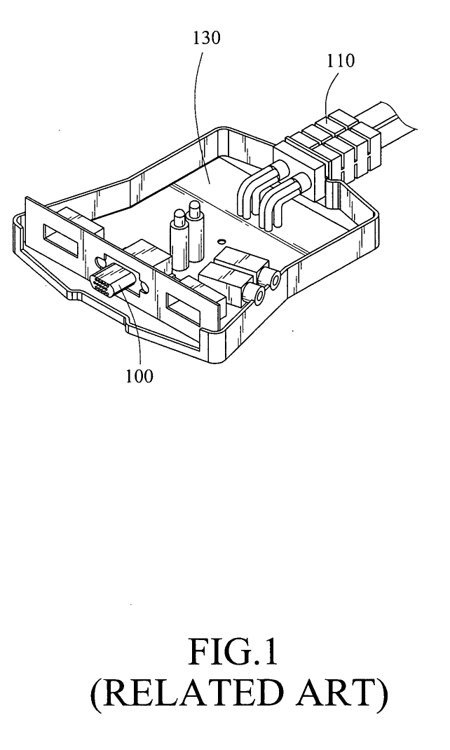

FIG. 2 is a perspective view of a switch device of the invention being connected with signal lines;

FIG. 3 is an exploded view of a switch device of the invention; and

FIG. 4 is a schematic diagram of application of the invention.

### DETAILED DESCRIPTION OF THE INVENTION

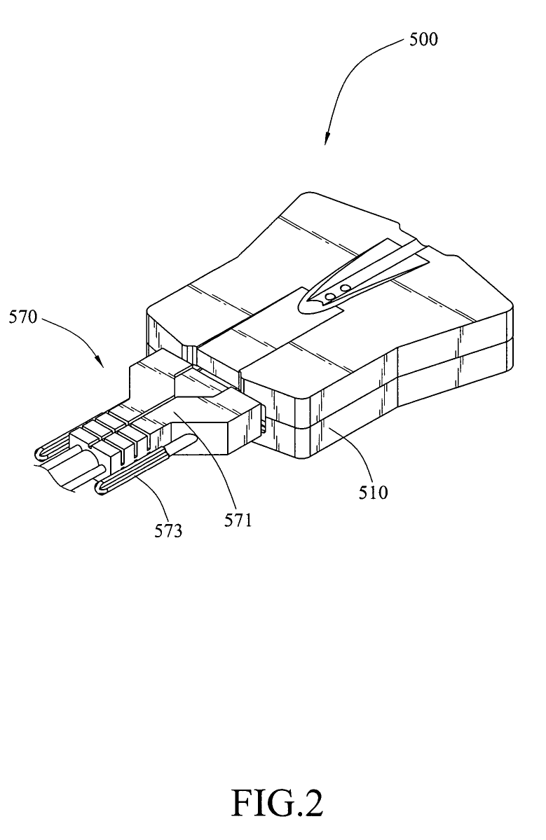

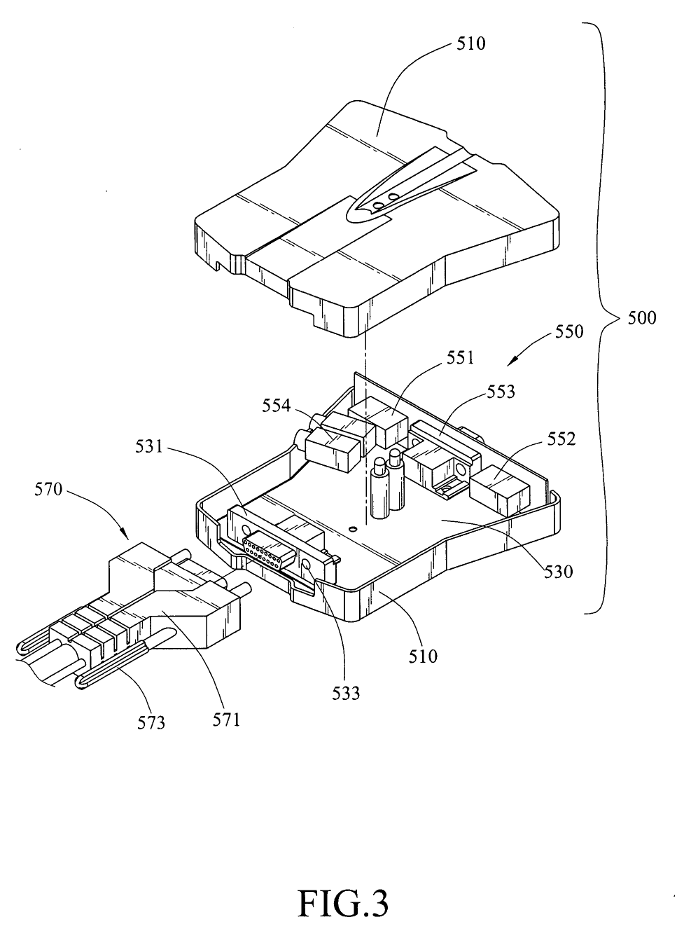

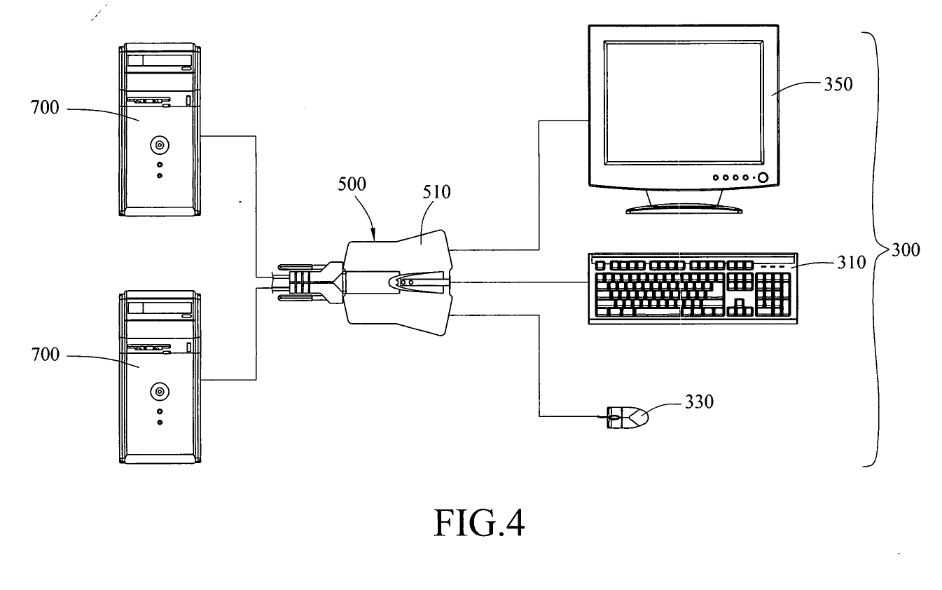

Please refer to FIGS. 2, 3, and 4, which are a perspective view, an exploded view, and an application diagram of the invention. The switch device 500 of the invention is used to control a plurality of controlled devices from a control element 300. The control element 300 can be a combination of a keyboard 310, a mouse 330, and a monitor 350 and the controlled device 700 can be a computer. The control element 300 is the input/output device of the computer; therefore, different computers, as controlled devices 700, are controlled by the control element 300 via the switch device 500. The function of the switch device 500 is used to switch and connect the control elements 300 to respectively control the different controlled devices 700.

The switch device 500 includes a circuit board 530 mounted inside a shell 510. The circuit board 530 is composed of electronic components (not shown in the drawing) for performing switch function of switching control signals from the control element 300 to a specific controlled device 700. The control element 300 is connected to the circuit board 530 via signal ports 550 mounted on the circuit board 530. The signal ports 550 corresponding to the control element 300 include a keyboard port 551, a mouse port 552, a monitor port 553 and so on. Others like a sound port 554 and so on are also applicable. Therefore, the control elements 300, such as the keyboard 310, the mouse 330, and the monitor 350, are connected respectively to the keyboard port 551, the mouse port 552, and the monitor port 553.

There are signal lines 570 connecting the circuit board 530 and the controlled device 700. In order to improve yield rate and ease of replacement of the signal lines 570, the signal lines 570 and the circuit board 530 are connected through a plug 571 and a socket 531. The circuit board 530 is equipped with the socket 531. The signal lines 570 are formed with the plug 571. The plug 571 is connected to the socket 531 so that the signal lines 570 are electrically connected to the circuit board 530 for controlling several controlled devices 700 at the other end of the signal lines 570.

In order to prevent the signal lines 570 and its plug 571 from being pulled off from the socket 531 by external force, there are two bolts 573 settled on the sides of the plug 571 for fixing the plug 571 to the socket 531 by fastening the bolts 573 into two screw holes 533, which are corresponding to the settled places of the two bolts 573, formed on the sides of the socket 531. By the bolts 573, the signal line 570 can be well connected to the socket 531 so as to avoid the signal line 570 coming off from the switch device 500.

Therefore, the circuit board of the invention is equipped with a socket; and the signal line is formed with a plug. After the manufacturing process, the plug and the socket are connected to each other. The plug on the signal line is made by an automated system that has high yield rate. The socket is first mounted on the circuit board then fixed by a soldering process. Because the pins of the socket are fixed, there is no problem of wrong pin location. Therefore, it also has a high yield rate.

Moreover, because the signal lines connected to the controlled devices are exposed to the environment, they are easy to be damaged due to careless using or other reasons. By the plug and socket arrangement, a damaged signal line is easy to be replaced by just being unplugged from the socket, and substituted by a new one. There is no need to release every single wire from the circuit board and solder every new wire as in a conventional signal line arrangement. Therefore, the invention is quite practical and useful that makes the switch device a convenient apparatus.

The invention being thus described, it will be obvious that the same may be varied in many ways. Such variations are not to be regarded as a. departure from the spirit and scope of the invention, and all such modifications as would be obvious to one skilled in the art are intended to be included within the scope of the following claims.

What is claimed is:

1. A switch device, comprising:
a shell;
a circuit board, fixed in said shell and mounted with a socket;
at least a signal port, electrically connected to said circuit board; and
a signal line, formed with a plug removably connected to said socket, for transferring signals to said signal port via said circuit board.

2. The switch device according to claim 1 wherein said signal port comprises a display port, a mouse port, and a keyboard port electrically connected to said circuit board.

3. The switch device according to claim 2 wherein said signal port further comprises a sound port electrically connected to said circuit board.

4. The switch device according to claim 1 wherein said plug is formed with two bolts settled on the sides of said plug for fixing said plug to said socket by fastening said bolts into two screw holes formed on sides of said socket so as to assure good connection.
